(19) United States
(12) Patent Application Publication
(10) Pub. No.: US 2005/0212148 A1
(43) Pub. Date: Sep. 29, 2005

(54) Semiconductor device

(75) Inventors: Kenji Otani, Kyoto-shi (JP); Masahiro Tsuji, Kyoto-shi (JP)

Correspondence Address: SUGHRUE MION, PLLC, 2100 PENNSYLVANIA AVENUE, N.W., SUITE 800, WASHINGTON, DC, 20037, US

(73) Assignee: ROHM CO., LTD.

(21) Appl. No.: 10/911,509

(22) Filed: Aug. 5, 2004

(30) Foreign Application Priority Data
Aug. 6, 2003 (JP) 2003-287813
Aug. 6, 2003 (JP) 2003-287814

(51) Int. Cl. H01L 23/28

(52) U.S. Cl. 257/787

(57) ABSTRACT

In order to minimize a distance from a power supply line and/or a ground line of a semiconductor integrated circuit of a semiconductor device to electrodes of a printed board, at least either a power supply electrode or the ground line of the semiconductor integrated circuit is connected to a metal film through openings provided in a protective film over the power supply electrode. The metal film is exposed on a side of the semiconductor device, adjacent to a printed board on which the semiconductor device is mounted, or on a side thereof, opposite from the printed board, and the metal film is connected a power supply electrode and/or a ground electrode of the printed board through the exposed surface of the metal film. Alternatively, upper and lower metal films connected to each other, with a stress relief film interposed therebetween, may be disposed in place of the metal film, or a metal sheet may be disposed over the metal film. Further, in order to minimize the length of a heat radiation path of the semiconductor integrated circuit of the semiconductor device, the protective film is deposited on the semiconductor integrated circuit, and the metal film is exposed on the side of the semiconductor device, adjacent to the printed board on which the semiconductor device is mounted, or on the side thereof, opposite from the printed board, thereby effecting heat radiation. Alternatively, the upper and lower metal films connected to each other, with the stress relief film interposed therebetween, may be disposed in place of the metal film, or a metal sheet functioning as a heat sink is disposed over the metal film.

### FIELD OF THE INVENTION

The present invention relates to a semiconductor device provided with a semiconductor integrated circuit, and in particular, to a semiconductor integrated circuit configured such that while wiring resistance is reduced when disposed on a circuit board, such as a printed circuit board, and so forth, and heat generated therein can be efficiently radiated.

### BACKGROUND OF THE INVENTION

With a conventional semiconductor device, outlets for internal electrodes of a semiconductor integrated circuit, such as a ground electrode or power source electrode, are generally disposed in a peripheral part of the semiconductor integrated circuit, and consequently, it has been necessary to connect internal elements of the semiconductor integrated circuit to the outlets for the electrodes, disposed in the peripheral part of the semiconductor integrated circuit by a very thin metal interconnection made of aluminum or copper, leading from the former, respectively. Further, connection of the outlets for the electrodes of the semiconductor integrated circuit to electrodes of a circuit board, such as a printed circuit board, and so forth, is implemented by bonding the electrodes of the semiconductor integrated circuit to so-called leads made of a copper alloy and so forth, such as metal sheets, bumps, or lands with a wire made of made of gold, aluminum, or copper, or with a bump made of gold, solder, tin, and so forth, respectively, and further, in order to protect the semiconductor integrated circuit, respective junctions of the semiconductor integrated circuit with the leads, bumps, or lands, and the leads, bumps, lands, or so on, from mechanical stress, and so on, these are all encapsulated with a synthetic resin such as epoxy resin, polyimide, and so forth.

On rare occasions, there is also a case where the outlets for the internal electrodes are provided in the vicinity of the center of the semiconductor integrated circuit, and connection to the leads is made with a wire leading from the outlets, respectively.

FIG. 17 is a schematic sectional view showing an example of a conventional semiconductor device although the same has not been described in any specific document. A semiconductor integrated circuit (IC chip) 10 of a semiconductor device 1 is attached onto a die pad 12 with an adhesive or solder, and while a protective film 26 is formed in the upper part of the semiconductor integrated circuit 10, in the figure, that is, an active surface thereof, wires 18 connected to the other end of a metal interconnection 20 with one end connected to internal electrodes of the semiconductor integrated circuit 10, through a plurality of electrode outlets 22, 24, provided in the protective film 26, respectively, are connected to leads 16, respectively. Further, in order to protect the semiconductor integrated circuit 10, respective junctions between the electrodes of the semiconductor integrated circuit and the leads 16 (or bumps, or lands), and the leads (or the bumps, or the lands), the semiconductor device 1 has a construction such that those are retained with a synthetic resin such as epoxy resin, polyimide, and so forth, that is, the same are encapsulated with a resin 28.

Thus, with the conventional semiconductor device 1, as it has been necessary to connect the internal electrodes of the semiconductor integrated circuit 10 to the electrode outlet 22 disposed in a peripheral part of the semiconductor integrated circuit 10 with the metal interconnection 20 which is very thin, and also to connect the electrode outlets 22, 24, of the semiconductor integrated circuit 10 to the leads 16, with the wires 18, respectively, a wiring length has become very long, and to that extent, an increase in electrical resistance value has resulted, thereby creating a main factor for deterioration in characteristics of the semiconductor device 1.

Further, with a semiconductor integrated circuit of a construction such that electrode outlets are provided in the vicinity of the center of the semiconductor integrated circuit, wiring resistance can be rendered somewhat lower than that for the semiconductor device 1 of the previously-described construction, however, there is the need for connecting the electrode outlets to the leads with a fine metal line, respectively, and respective lengths of the fine metal lines become longer, so that it has been unavoidable to bring about an increase in electrical resistance value anyway, thereby creating a main factor for deterioration in characteristics of a semiconductor device.

Along with recent increases in degree of integration of the IC chip, there have been further advances toward miniaturization of the semiconductor integrated circuit. As a result, there is a tendency of metal interconnections and fine metal lines becoming increasingly thinner, so that the deterioration in the characteristics, due to the main factor as described, is seen increasingly pronounced.

Among semiconductor devices, there has been known the semiconductor device of a construction in which an IC chip is provided with metal protrusions (metal bumps), and a metal member (metal bar) is mounted on the metal protrusions to thereby secure both together with, for example, a nonconducting adhesive, and so forth, before exposing the end of the metal bar (refer to JP-A7-66332), which is, however, intended to exclusively dissipate heat, and the metal bar is not connected to the electrodes of the IC chip.

Further, as a result of the increases in the degree of integration of the IC chip, a processing speed thereof has become very fast, and as the degree of integration of the IC chip and the processing speed thereof increase, so does a current amount flowing per unit time, so that there is a tendency of heat quantity of the IC chip increasing.

Upon an increase in heat quantity of the semiconductor integrated circuit, leak current increases, causing not only a problem of deterioration in reliability, and so forth, but also a problem of a gap developed between respective elements of the semiconductor device, due to difference in coefficient of thermal expansion between the respective elements. Such gaps will cause not only a problem of faulty contact, but also a problem that foreign matter, such as moisture, and so forth, makes ingress in the interior from outside, and if heat generation occurs to the semiconductor device in such a state, the foreign matter, such as moisture, and so forth, having made ingress in the interior will undergo expansion, thereby causing even destruction of the semiconductor device.

In addition, with a semiconductor device having a high degree of integration, since there is an increase in the number of input/output electrodes (pads), and the number of power source electrodes, within the semiconductor device, spacing between the electrodes becomes narrower, so that leads become inevitably thinner, resulting in a problem of poor heat radiation characteristics.

Hence, there have thus far been proposed heat radiation means, for example, as described hereinafter.
(1) heat radiation means whereby a die pad is exposed on the top surface or the back surface of a semiconductor device, and heat is radiated from the die pad as exposed to a printed board or an enclosure of electronic equipment (refer to JP-A100709/2002, and JP-A9-260568).
(2) heat radiation means whereby a die pad is connected to inner leads, and a heat radiation sheet is bonded to the inner leads connected to the die pad through the intermediary of an insulation layer to thereby radiate heat of a printed board (refer to JP-A8-55947).
(3) heat radiation means whereby a die pad is bonded to all leads with a tape-like adhesive, and heat is radiated to a printed board through the leads (refer to JP-A5-144991).
(4) heat radiation means whereby an IC chip is provided with metal protrusions (metal bumps), a metal member (metal bar) is mounted on each of the metal protrusions, a copper sheet called a heat sink is bonded to the metal members (metal bars), and the heat sink is exposed on the surface of a semiconductor device, thereby radiating heat from the heat sink as exposed or from metallic members also provided in the back surface of a die pad and exposed thereon to a printed board or an enclosure of electronic equipment (refer to JP-A7-66332).

However, in the case of radiating heat from the back surface side of a semiconductor integrated circuit through the die pad, as described under (1) above, it is the common practice to use an electrically conductive adhesive, insulating adhesive, solder, and so forth, as means for bonding the semiconductor integrated circuit with the die pad. In the case of bonding the semiconductor integrated circuit with the die pad by use of these adhesives, solder, and so forth, it is extremely difficult based on the current fabrication technology to completely eliminate voids contained in the adhesives, or solder, and furthermore, if the semiconductor integrated circuit is bonded with the die pad by use of the adhesives, there is no denying a possibility that exfoliation of the die pad from the semiconductor integrated circuit occurs due to thermal stress developed at the time when the semiconductor device is mounted on a circuit board. For this reason, the means have shortcomings in that heat radiation characteristics of the semiconductor device largely fluctuate, and the characteristics undergo variation. Further, in the case of radiating heat from the back surface side of the conventional semiconductor integrated circuit through the die pad, a heat radiation path tends to become longer, so that there has been a tendency of thermal resistance between junction cases becoming higher. Hence, even if the semiconductor device as a whole meets a permissible loss against heat generation, there exists a risk of the semiconductor device undergoing thermal destruction due to localized heat generation of the semiconductor integrated circuit.

Further, with the heat radiation means whereby the die pad is connected to the inner leads, and the heat radiation sheet is bonded to the inner leads connected to the die pad through the intermediary of the insulation layer to thereby radiate heat of the printed board as described under (2) above, and with the heat radiation means whereby the die pad is bonded to all the leads with the tape-like adhesive, and heat is radiated to the printed board through the leads as described under (3) above, there is a tendency that a heat radiation path becomes longer than that in the case of (1) above, thereby causing a problem of an increase in thermal resistance.

In the case of (4) above, a construction is adopted such that in order to radiate heat generated in the IC chip to the outside at the shortest distance from the metal protrusions through the respective metal members, the IC chip is provided with the metal protrusions (metal bumps) on which the metal member (metal bar) is mounted to secured both together with, for example, a nonconducting adhesive, and so forth, so that the construction is complex, and consequently, fabrication becomes complicated, resulting in high cost.

### SUMMARY OF THE INVENTION

The invention has been developed to resolve the above-described problems with the conventional semiconductor device, and it is a first object of the invention to significantly reduce wiring resistance from elements inside a semiconductor integrated circuit of a semiconductor device up to external terminals of a printed board, and so forth, thereby checking deterioration in characteristics of the semiconductor device to the minimum.

A second object of the invention is to minimize the length of a heat radiation path from the semiconductor integrated circuit, thereby significantly reducing thermal resistance between junction cases.

A third object of the invention is to preclude deterioration in heat radiation characteristics, due to variation in condition of bonding between the semiconductor integrated circuit, and a die pad.

A fourth object of the invention is to enhance resistance to thermal destruction due to localized heat generation occurring inside the semiconductor integrated circuit.

In accordance with a first aspect of the invention, there is provided a semiconductor device encapsulated with a resin, comprising a semiconductor integrated circuit, and conduction means for connecting electrode terminals of the semiconductor integrated circuit to electrodes of a board, respectively, said semiconductor device further comprising a protective film, and a metal film, deposited in that order over the semiconductor integrated circuit, wherein the metal film is exposed from the resin for encapsulation on the top surface side or the back surface of the semiconductor device.

The invention provides in its second aspect a semiconductor device encapsulated with a resin, comprising a semiconductor integrated circuit, and conduction means for connecting electrode terminals of the semiconductor integrated circuit to electrodes of a board, respectively, said semiconductor device further comprising a protective film, and a metal film, deposited in that order over the semiconductor integrated circuit, wherein the metal film is connected to internal electrodes of the semiconductor integrated circuit through openings provided in the protective film, and is exposed from the resin for encapsulation on the top surface side or the back surface of the semiconductor device.

With the semiconductor device having those features described, the metal film is preferably provided with a stress relief film.

Further, with the semiconductor device as described above, the metal film may comprise first and second metal films, the first and second metal films being connected with each other via at least one spot, with the stress relief film interposed therebetween, and the second metal film may be exposed from the resin for encapsulation on the top surface side or the back surface of the semiconductor device.

Still further, the semiconductor device described in the foregoing may further comprise a metal sheet bonded to the first metal film, and the metal sheet may be exposed from the resin for encapsulation on the top surface side or the back surface of the semiconductor device.

Yet further, the semiconductor device described above may further comprise a metal sheet bonded to the second metal film, and the metal sheet may be exposed from the resin for encapsulation on the top surface side or the back surface of the semiconductor device.

Further, the first and second metal films are preferably made of gold, aluminum, copper, or an alloy composed of these elements as main constituents, respectively, and the stress relief film may be made of an elastomer or a plastomer, such as a polyimide, an epoxy resin, and so forth.

Still further, the semiconductor device described above comprises a die pad with the semiconductor integrated circuit mounted thereon, and the die pad may be exposed from the resin for encapsulation on the top surface side or the back surface of the semiconductor device.

Yet further, the surface of the metal film or the metal sheet, made of an element other than gold, that is exposed from the resin for encapsulation on the top surface side or the back surface of the semiconductor device, preferably has a gold plating.

The present invention has the following advantages:
(1) It becomes possible to bond the internal electrodes of the semiconductor integrated circuit inside the semiconductor device to the electrodes of the circuit board by way of the shortest distance, so that wiring resistance can be significantly reduced. As a result, a fast and downsized semiconductor device can be stably operated.
(2) By providing the metal film with the stress relief film, it is possible to enhance the resistance to thermal destruction due to localized heat generation occurring inside the semiconductor integrated circuit. That is, thermal stress occurring inside the semiconductor device, due to heat generated in the semiconductor integrated circuit, can be relieved, thereby preventing troubles due to exfoliation between respective elements joined together, and so forth.
(3) Heat generated in the semiconductor integrated circuit can be radiated from substantially the entire face of the semiconductor integrated circuit, on the surface side thereof, by way of the shortest distance. That is, by minimizing the length of the heat radiation path from the semiconductor integrated circuit, thermal resistance between the junction cases can be significantly reduced.
(4) As heat is radiated mainly from the semiconductor integrated circuit side, deterioration in heat radiation characteristics, due to variation in the condition of bonding between the semiconductor integrated circuit, and the die pad, can be precluded.
(5) Because heat can also be radiated from the back surface side of the conventional semiconductor integrated circuit through the die pad, the heat radiation efficiency of the semiconductor device can be further enhanced.

### BRIEF DESCRIPTION OF THE DRAWINGS

FIG. 1 is a schematic sectional view of a first embodiment of a semiconductor device according to the invention;

FIG. 2 is a schematic sectional view of a second embodiment of a semiconductor device according to the invention;

FIG. 3 is a schematic sectional view of a third embodiment of a semiconductor device according to the invention;

FIG. 4 is a schematic sectional view of a fourth embodiment of a semiconductor device according to the invention;

FIG. 5 is a schematic sectional view of a fifth embodiment of a semiconductor device according to the invention;

FIG. 6 is a schematic sectional view of a sixth embodiment of a semiconductor device according to the invention;

FIG. 7 is a schematic sectional view of a seventh embodiment of a semiconductor device according to the invention;

FIG. 8 is a schematic sectional view of an eighth embodiment of a semiconductor device according to the invention;

FIG. 9 is a schematic sectional view of a ninth embodiment of a semiconductor device according to the invention;

FIG. 10 is a schematic sectional view of a tenth embodiment of a semiconductor device according to the invention;

FIG. 11 is a schematic sectional view of an eleventh embodiment of a semiconductor device according to the invention;

FIG. 12 is a schematic sectional view of a twelfth embodiment of a semiconductor device according to the invention;

FIG. 13 is a schematic sectional view of a thirteenth embodiment of a semiconductor device according to the invention;

FIG. 14 is a schematic sectional view of a fourteenth embodiment of a semiconductor device according to the invention;

FIG. 15 is a schematic sectional view of a fifteenth embodiment of a semiconductor device according to the invention;

FIG. 16 is a schematic sectional view of a sixteenth embodiment of a semiconductor device according to the invention; and

FIG. 17 is a schematic sectional view of a conventional semiconductor device.

### PREFERRED EMBODIMENTS OF THE INVENTION

Embodiments of the invention are described hereinafter with reference to the accompanying drawings.

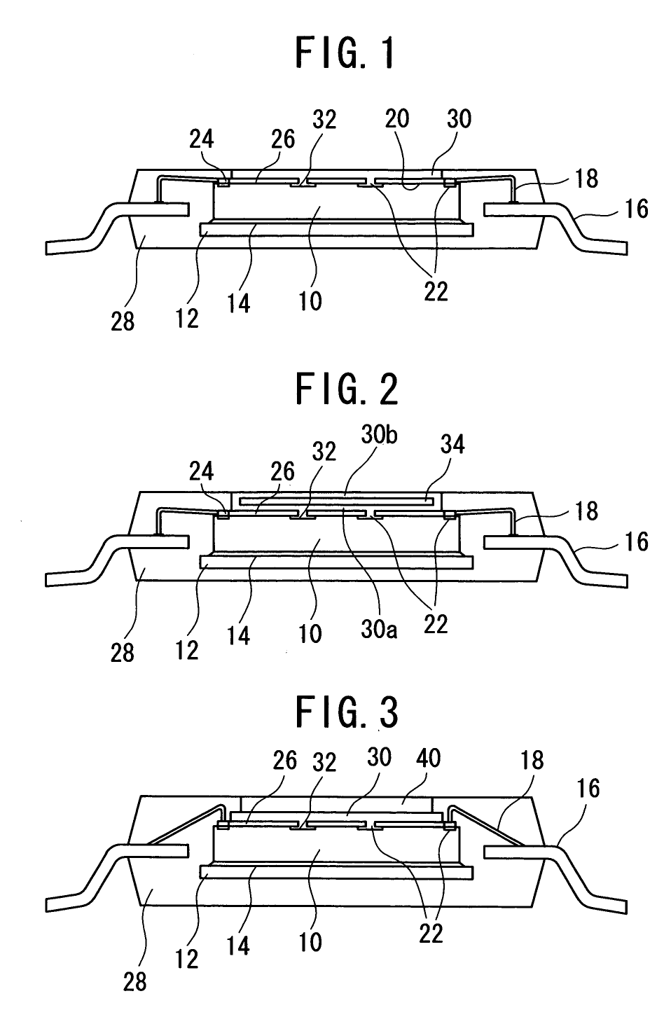

FIG. 1 is a schematic sectional view of a first embodiment of a semiconductor device according to the invention, and in the figure, parts corresponding to those for the conventional semiconductor device are denoted by like reference numerals. More specifically, a semiconductor integrated circuit 10 of a semiconductor device 1 is installed on top of a die pad 12 with an adhesive or solder, and in the upper part of the semiconductor integrated circuit 10, in the figure, that is, over an active surface thereof, there is formed a protective film 26. Further, wires 18 connected to a metal interconnection 20 of the semiconductor integrated circuit 10 through a plurality of electrode outlets 22, 24, provided in the protective film 26, respectively, are connected to leads 16, respectively, and the semiconductor integrated circuit 10, the die pad 12, the wires 18, the metal interconnection 20, the protective film 26, and so forth are encapsulated with an epoxy resin 28.

Now, with the present embodiment, an electrode outlet 32 for taking out at least either a ground line or a power supply line of the semiconductor integrated circuit, is provided at one spot or a plurality of spots in optional locations of the active surface of the semiconductor integrated circuit 10, in addition to the electrode outlets 22, 24, as for the conventional case, and portions of the protective film 26, corresponding thereto, are removed.

Over portions of the protective film 26, excluding openings of the protective film 26, other than the electrode outlet 32 for connection with external terminals of the semiconductor integrated circuit 10, a metal film 30 made of gold, aluminum, or copper, or an alloy composed of these, as main constituents, is deposited by a vapor deposition method or a plating method. The metal film to be formed preferably corresponds in size to approximately 60 to 80% of a region of the protective film 26, excluding the openings of the protective film 26, other than the electrode outlet 32 for connection with the external terminals of the semiconductor integrated circuit. By so doing, either the ground line or the power supply line of the semiconductor integrated circuit is bonded to the metal film 30 formed over the protective film 26.

The metal film 30 is exposed from the epoxy resin 28 covering the semiconductor device 1, and by connecting the metal film 30 as exposed with electrodes (not shown) of a printed board, connection to an electrode (a power supply electrode, or ground electrode) of the semiconductor integrated circuit 10 can be implemented without use of a long metal interconnection as required in the conventional case. Furthermore, heat generated in the semiconductor integrated circuit 10 can be radiated to the outside via the metal film 30. That is, the metal film 30 is exposed from the epoxy resin 28 covering the semiconductor integrated circuit 10, and, through the intermediary of the metal film 30 as exposed, the heat generated in the semiconductor integrated circuit 10 can be radiated to an enclosure, and so forth, of electronic equipment bonded to the semiconductor integrated circuit 10, or into the atmosphere.

FIG. 2 is a schematic sectional view of a second embodiment of a semiconductor device according to the invention. The semiconductor device according to the present embodiment is the same in basic construction as the semiconductor device shown in FIG. 1 except that in place of the metal film 30 in the semiconductor device 1 according to the first embodiment, a stress relief film 34 made of polyimide, and so forth is further provided over a metal film 30a formed over a protective film 26 in order to relieve stress occurring between a semiconductor integrated circuit 10 and exposed parts of a semiconductor device 1, and further over the stress relief film 34, a metal film 30b made of, for example, gold, aluminum, copper, or an alloy composed of these elements as main constituents is deposited by the vapor deposition method or the plating method. The metal film 30b in an upper layer as seen from the semiconductor integrated circuit is exposed from an epoxy resin 28 encapsulating the semiconductor device 1, and the metal film 30b as exposed is connected with electrodes (not shown) of a printed board, the metal film 30a in the lower layer being connected with the metal film 30b in the upper layer via at least one spot. With the adoption of such a configuration as described, as with the case of the first embodiment, internal electrodes (internal elements) of the semiconductor integrated circuit 10 can be connected to a power supply line, or a ground line, without use of a long metal interconnection as required in the conventional case. Further, since the metal film 30b in the upper layer is exposed from the epoxy resin 28 covering the semiconductor device 1, the metal film 30b as exposed is connected to an enclosure, and so forth, of electronic equipment, and the metal film 30a in the lower layer is connected with the metal film 30b in the upper layer via at least one spot, heat generated in the semiconductor integrated circuit 10 can be conducted through metallic parts to be thereby radiated to the enclosure, and so forth, of electronic equipment, bonded to the metal film 30b in the upper layer.

Furthermore, because the stress relief film 34 is provided, it is possible to prevent occurrence of problems such that repetition in heating and cooling of the semiconductor device 1 when the same is in operation, and out of operation will cause exfoliation to occurs to joined parts due to difference in coefficient of thermal expansion between respective elements inside the semiconductor device 1, resulting in breakage of the semiconductor device 1 or faulty connections, and so forth.

FIG. 3 is a schematic sectional view of a third embodiment of a semiconductor device according to the invention. The present embodiment has a construction in which a metal sheet 40 made of gold, copper, and so forth is disposed over the metal film 30 in the semiconductor device 1 according the first embodiment. The construction is suitable in the case where as a semiconductor integrated circuit 10 is at a distance away from the top surface or back surface of a semiconductor device 1, it is not preferable from the viewpoint of productivity as well as economics to expose the metal film 30 to the top surface or back surface of the semiconductor device 1, and in this case, the metal sheet, made of gold, aluminum, copper, or an alloy composed of these elements, as main constituents, is bonded to the metal film, thereby exposing the metal sheet on the top surface or back surface of the semiconductor device 1.

With the adoption of such a configuration as described, as with the case of the first embodiment, internal electrodes of the semiconductor integrated circuit 10 can be connected to a power supply line, or a ground line, without use of a long metal interconnection as required in the conventional case.

Because the metal sheet 40 functions as a heat sink, radiation of heat generated in the semiconductor integrated circuit 10 can be further promoted. In this case, the metal film 30 is preferably bonded to the metal sheet 40 by gold-tin bonding or by high-temperature soldering, and further, the exposed surface of the metal sheet 40 is preferably plated with gold if the metal sheet 40 is made of an element other than gold, or with solder, or tin. With such a configuration as described, heat can be not only temporarily accumulated in the metal sheet 40 owing to thermal capacity thereof, but also radiated from the surface thereof to the outside, so that heat radiation can be effected more efficiently.

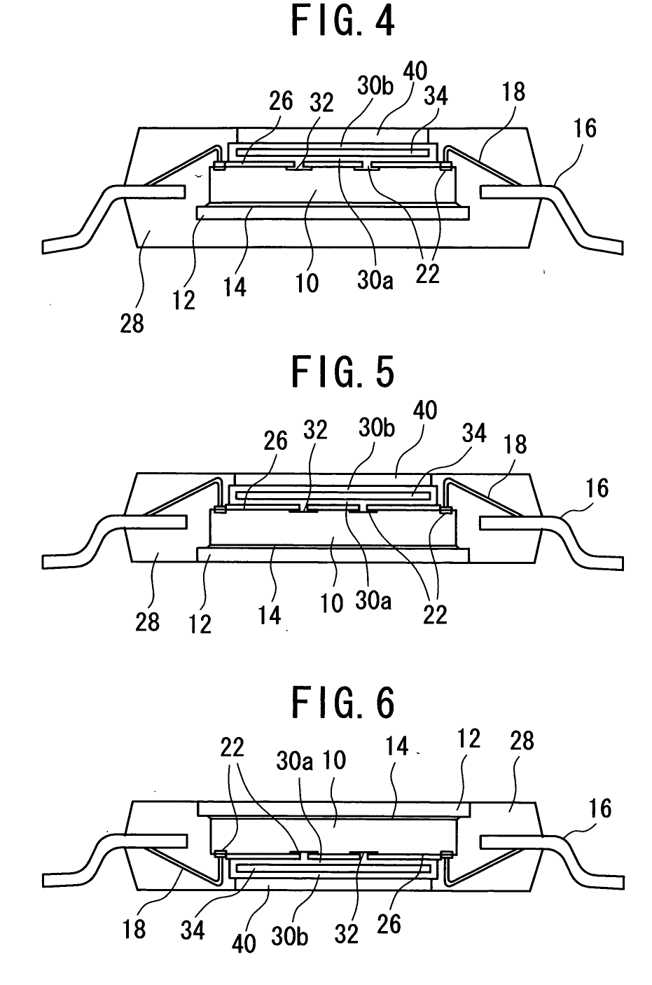

FIG. 4 is a schematic sectional view of a fourth embodiment of a semiconductor device according to the invention. The present embodiment has a construction in which the metal sheet 40 according to the third embodiment is disposed over the metal film 30b in the upper layer of the second embodiment.

More specifically, the semiconductor device according to the fourth embodiment is constructed such that a stress relief film 34 made of polyimide, and so forth is further provided over a metal film 30a formed over a protective film 26, a metal film 30b made of, for example, gold, aluminum, copper, or an alloy composed of these elements as main constituents is deposited over the stress relief film 34 by the vapor deposition method or the plating method, and so forth, and, further, there is disposed a metal sheet 40 over the metal film 30b. In this case as well, the metal film 30a in the lower layer is connected to the metal film 30b in the upper layer via at least one spot.

Accordingly, the semiconductor device 1 according to the present embodiment has the operation effects of the second embodiment in combination with those of the third embodiment. That is, by connecting the semiconductor integrated circuit 10 to a power supply line, or a ground line, without use of a long metal interconnection as required in the conventional case, not only radiation of heat from the semiconductor integrated circuit 10 can be further promoted through the metal sheet 40 functioning as the heat sink, but also thermal stress occurring to the metal sheet 40, due to heat generation in semiconductor, can be relieved by the stress relief film 34, so that exfoliation at junction parts, and formation of gaps can be prevented with reliability, thereby enabling the semiconductor device 1 to perform stable operation all the time without undergoing breakage.

FIG. 5 is a schematic sectional view of a fifth embodiment of a semiconductor device according to the invention. The present embodiment has a construction in which the underside of a die pad 12 in the fourth embodiment is exposed from an epoxy resin for encapsulation, thereby causing the die pad 12 to come into direct contact with a printed board upon mounting a semiconductor integrated circuit thereon. With the adoption of such a configuration as described, heat generated in the semiconductor integrated circuit 10 can be radiated to the outside through metal films 30a, 30b and a metal sheet 40 besides being radiated to the printed board through the die pad 12, so that heat radiation efficiency of the semiconductor device is further enhanced.

FIG. 6 is a schematic sectional view of a sixth embodiment of a semiconductor device according to the invention, and with the present embodiment, the die pad 12, the semiconductor integrated circuit 10, a protective film 26, the first metal film 30a, a stress relief film 34, the second metal 30b, and the metal sheet 40, in the semiconductor device 1 shown in FIG. 5, are disposed in an inverted position, thereby connecting the semiconductor integrated circuit 10 to leads 16 through the intermediary of wires 18, respectively.

With such a construction as described, since the metal sheet 40 is directly connected to a printed circuit board, wiring resistance can be further reduced, and further, with the construction described, as the metal sheet 40 is in direct contact with the printed circuit board upon mounting the semiconductor integrated circuit thereon, heat generated in the semiconductor integrated circuit 10 can be radiated directly to the printed board through the intermediary of the metal sheet 40 in addition to the heat radiation efficiency of the fifth embodiment, and as the die pad 12 is exposed from an epoxy resin for encapsulation, the heat generated in the semiconductor integrated circuit 10 can be radiated from the die pad 12 as well to the outside through an enclosure, and so forth, of electronic equipment, bonded to the die pad 12. Hence, with the configuration described, efficient heat radiation can be effected.

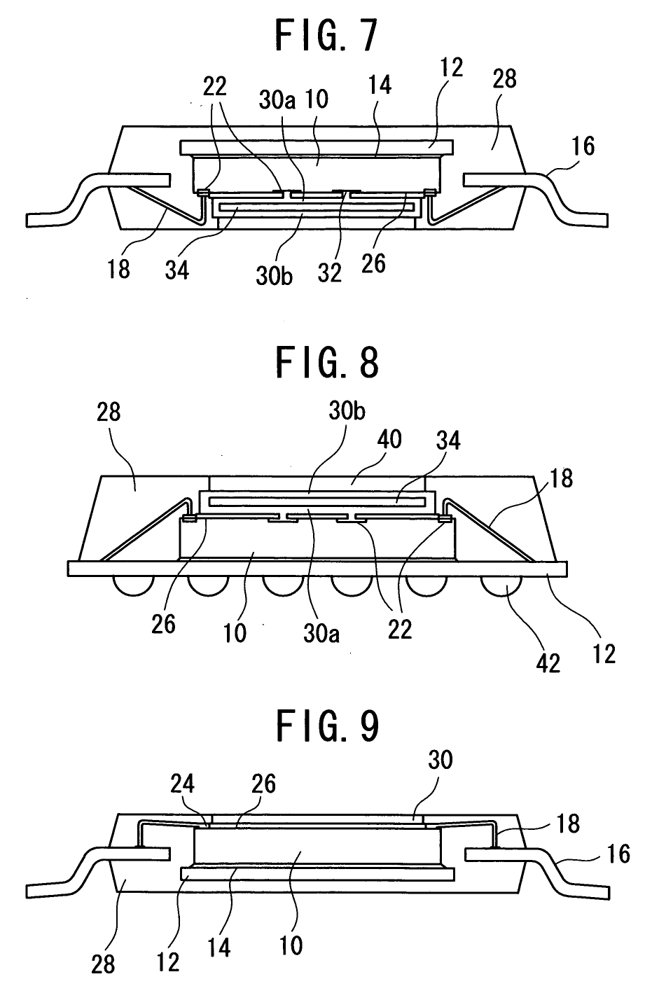

FIG. 7 is a schematic sectional view of a seventh embodiment of a semiconductor device according to the invention, having a construction in which the die pad 12, the semiconductor integrated circuit 10, the protective film 26, the first metal film 30a, the stress relief film 34, the second metal 30b, and the metal sheet 40, in the semiconductor device 1 shown in FIG. 4, are disposed in an inverted position, thereby connecting the semiconductor integrated circuit 10 to leads 16 through the intermediary of wires 18, respectively.

With the construction described as well, because a metal sheet is directly connected to a printed circuit board, the metal sheet can be connected to electrodes of the circuit board by way of a still shorter distance, and to that extent, resistance can be reduced, and at the same time, heat generated in the semiconductor integrated circuit 10 can be radiated to the printed circuit board through the metal sheet 40. Other operation effects of the present embodiment are the same as those of the semiconductor device 1 described with reference to FIG. 4.

FIG. 8 is a schematic sectional view of an eighth embodiment of a semiconductor device according to the invention. With the present embodiment, wires 18 are bonded to a die pad 12, a plurality of bumps 42 are provided on the underside of the die pad 12, and a semiconductor integrated circuit 10 is connected to, for example, electrodes of a printed circuit board through the intermediary of the plurality of the bumps 42. Configuration of the present embodiment, in other respects, is the same as that for the semiconductor device 1 shown in FIG. 5 and the operation effects of the present embodiment also are the same as those for the latter.

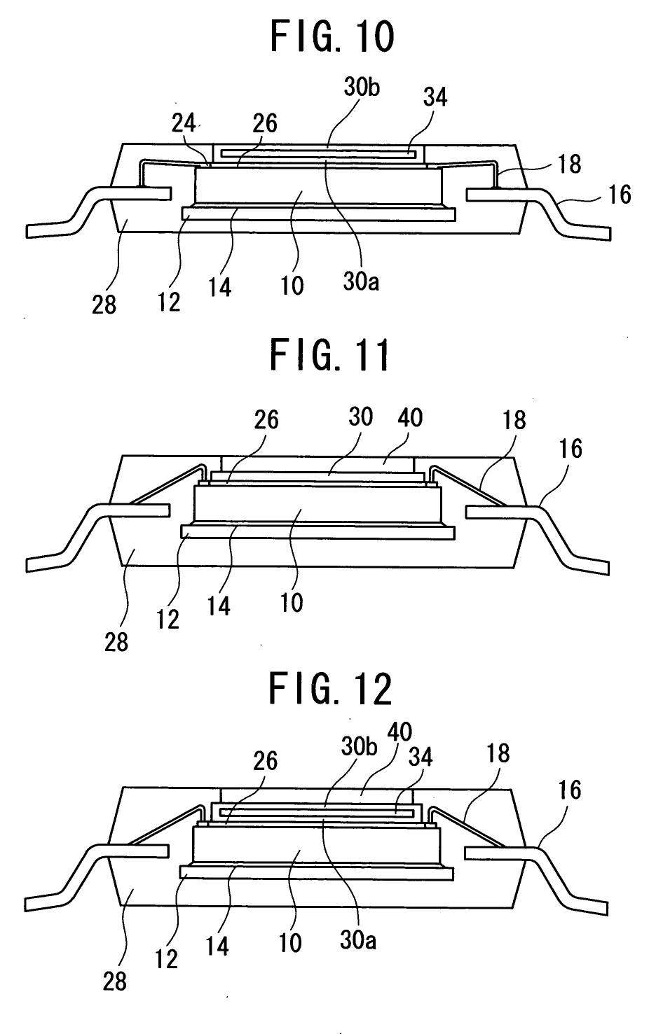

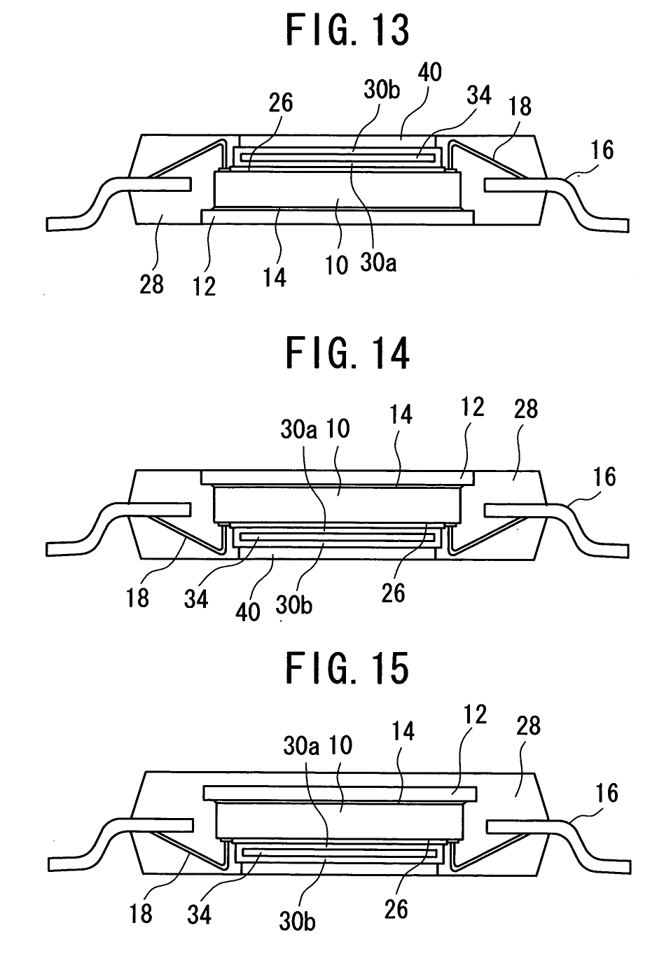

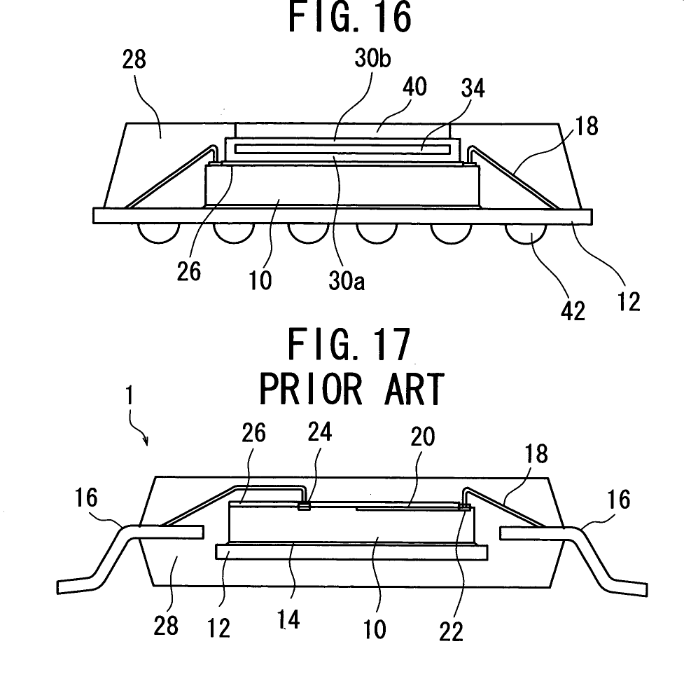

FIGS. 9 to 16 are schematic sectional views of ninth to sixteenth embodiments of a semiconductor device according to the invention, respectively. The ninth to sixteenth embodiments are the same in construction as the first to eighth embodiments, respectively, except for the electrode outlets 22, and 32 that are provided in the first to eighth embodiments, respectively, and the operation effects of the former are the same as those of the latter, respectively, omitting therefore detailed description thereof.

With the respective embodiments described in the foregoing, if the metal film 30 or the metal sheet 40 is made of material other than gold, the exposed surface of the metal film 30 or the metal sheet 40 is preferably plated with gold, solder, or tin in order to protect the interior of the semiconductor device 1 to thereby implement prevention of corrosion thereof, and so forth.

1. A semiconductor device encapsulated with a resin, comprising a semiconductor integrated circuit, and conduction means for connecting electrode terminals of the semiconductor integrated circuit to electrodes of a board, respectively, said semiconductor device further comprising:
a protective film, and a metal film, deposited in that order over the semiconductor integrated circuit, wherein the metal film is exposed from the resin for encapsulation on the top surface side or the back surface of the semiconductor device.

2. A semiconductor device encapsulated with a resin, comprising a semiconductor integrated circuit, and conduction means for connecting electrode terminals of the semiconductor integrated circuit to electrodes of a board, respectively, said semiconductor device further comprising:
a protective film, and a metal film, deposited in that order over the semiconductor integrated circuit, wherein the metal film is connected to internal electrodes of the semiconductor integrated circuit through openings provided in the protective film, and is exposed from the resin for encapsulation on the top surface side or the back surface of the semiconductor device.

3. A semiconductor device according to claim 1 or 2, wherein the metal film is provided with a stress relief film.

4. A semiconductor device according to claim 3, wherein the metal film may comprise first and second metal films, and the first and second metal films are connected with each other via at least one spot, with the stress relief film interposed therebetween, and the second metal film is exposed from the resin for encapsulation on the top surface side or the back surface of the semiconductor device.

5. A semiconductor device according to claim 1 or 2, further comprising a metal sheet bonded to the first metal film, wherein the metal sheet is exposed from the resin for encapsulation on the top surface side or the back surface of the semiconductor device.

6. A semiconductor device according to claim 3 or 4, further comprising a metal sheet bonded to the second metal film, wherein the metal sheet may be exposed from the resin for encapsulation on the top surface side or the back surface of the semiconductor device.

7. A semiconductor device according to any of claims 1 to 6, wherein the first and second metal films are made of gold, aluminum, copper, or an alloy composed of these elements as main constituents, respectively, and the stress relief film is made of an elastomer or a plastomer, such as a polyimide, an epoxy resin, and so forth.

8. A semiconductor device according to any of claims 1 to 7, further comprising a die pad with the semiconductor integrated circuit mounted thereon, wherein the die pad is exposed from the resin for encapsulation on the top surface side or the back surface of the semiconductor device.

9. A semiconductor device according to any of claims 1 to 8, wherein the surface of the metal film or the metal sheet, made of an element other than gold, that is exposed from the resin for encapsulation on the top surface side or the back surface of the semiconductor device has a gold plating.
